(19) United States
(12) Patent Application Publication
(10) Pub. No.: US 2026/0104491 A1
(43) Pub. Date: Apr. 16, 2026

(54) NEAR-INFRARED LASER PACKAGE FOR AUTONOMOUS DRIVING SENSOR

(71) Applicants: HYUNDAI MOTOR COMPANY, Seoul (KR); KIA CORPORATION, Seoul (KR)

(72) Inventors: Kyoung-Chun KWEON, Hwaseong-si (KR); Seon-Yong AN, Hwaseong-si (KR); Sae-Ah KIM, Hwaseong-si (KR)

(21) Appl. No.: 19/098,336

(22) Filed: Apr. 2, 2025

(30) Foreign Application Priority Data
Oct. 10, 2024 (KR) 10-2024-0137611

(51) Int. Cl. G01S 7/481; G01S 17/931; H01S 5/02345; H01S 5/042

(52) U.S. Cl. CPC G01S 7/4814; G01S 17/931; H01S 5/02345; H01S 5/04252; H01S 5/04256

(57) ABSTRACT

A near-infrared laser package for an autonomous driving sensor includes a cap having a mounting space therein, a stem extending to the mounting space through the cap, a submount disposed on the stem, a semiconductor chip mounted on the submount; and an anode extending to the mounting space through the cap and electrically connected to the semiconductor chip. The semiconductor chip is electrically connected to the stem through the submount. The package increases the heat transfer efficiency of the chip and reduces temperature dependency by increasing the heat dissipation through the electrode-junction layer-light emitting layer section.

### CROSS-REFERENCE TO RELATED APPLICATION

This application claims priority to Korean Patent Application No. 10-2024-0137611, filed on Oct. 10, 2024, which is incorporated herein by reference in its entirety.

### TECHNICAL FIELD

The present disclosure relates to a near-infrared laser package structure applied to an autonomous driving sensor.

### BACKGROUND

Near-infrared lasers may be used in an autonomous driving sensor. For example, a light detection and ranging (LiDAR) sensor, may use a wavelength of 905 nm. A method of sensing may be a time of flight (ToF), where a distance can be calculated by calculating the time it takes for light of the near-infrared laser to hit a target object and return. In some cases, where the higher a light output value of the near-infrared laser, the greater the intensity of light, the laser can be shot farther, and a detection distance increases from the perspective of the sensor.

To increase an output of the near-infrared laser, a mechanism may be provided in which a current is applied to a near-infrared semiconductor package and light is emitted due to the applied current. For instance, a semiconductor layer may be stacked using materials with different band gaps, and light may be emitted from a layer called a quantum well. In some cases, a semiconductor material with an InGaAs/GaAs stacked structure may be used as a light-emitting layer, and a p-n junction structure may be formed through P-type doping/n-type doping of the semiconductor to induce energy emission due to a combination of electrons and holes when power is applied to an LD(Laser Diode).

In some cases, where the efficiency of converting such a current into light is low, remaining energies may appear in the form of “heat” rather than light. The output of the near-infrared laser may be reduced due to such heat, and a spectrum (main wavelength) of the light may also shift. When such heat continues, the semiconductor may be degraded in the active layer from which heat is generated.

FIGS. 1 and 2 are an example result of quantum well layer analysis (STEM analysis), and FIG. 2 is a box portion of FIG. 1. In addition, FIGS. 3 and 4 show an example of the degradation of the quantum well layer after high-temperature degradation.

For example, at 95° C., optical power of a 75 W LD decreases by about 10%, and a main wavelength changes by 10 nm or more. In addition, optical power of a 120 W LD decreases by about 43% and a main wavelength changes by 20 nm or more.

In some cases, to address semiconductor degradation, heat resistance or the movement of carriers may be adjusted by changing a semiconductor layer. For instance, a method may reduce heat resistance by reducing the thickness of a stack structure in order to reduce temperature dependency. In some cases, a method may reduce confinement loss of radio waves in a quantum well under a high temperature through adjustment of a bandgap.

Some methods may be achieved through high technological maturity for epitaxial growth, and manufacturing and verification test levels that enable bandgap control through long-term T/O(Try-Out), which may cause a decrease in a room temperature output.

In some cases, the near-infrared laser package has a structure that electrically connects a chip to electrodes through bonding wires to apply a current. The bonding wire may thermally shrink and expand due to a change in temperature and is deformed after thermal shock test. Such deformation may affect optical characteristics such as reduced light output.

### SUMMARY

The present disclosure describes a near-infrared laser package for an autonomous driving sensor, which is capable of increasing heat transfer efficiency of a chip to package through material and structure development of a package, and reducing temperature dependency by increasing the heat dissipation effect through an electrode-junction layer-light-emitting layer (active layer) section.

According to one aspect of the subject matter described in this application, a near-infrared laser package for an autonomous driving sensor includes a cap that defines a mounting space therein, a stem that passes through the cap and extends to the mounting space, a submount disposed at the stem, a semiconductor chip mounted to the submount and electrically connected to the stem through the submount, and an anode that passes through the cap and extends to the mounting space, the anode being electrically connected to the semiconductor chip.

Implementations according to this aspect can include one or more of the following features. For example, the stem can be a cathode that is made of a copper (Cu) material. In some examples, the submount can be made of a silicon (Si) material. The stem can be configured to discharge heat generated from the semiconductor chip through the submount. In some implementations, the submount can be in contact with and face the semiconductor chip. In some implementations, the anode can face a surface of the semiconductor chip. In some examples, the near-infrared laser package can further include a solder wire that connects the anode to the semiconductor chip.

In some examples, the cathode and the anode are spaced apart from each other. In some examples, the cathode can be disposed at a first side with respect to the semiconductor chip, and the anode can be disposed at a second side with respect to the semiconductor chip opposite to the first side.

In some implementations, the submount can have (i) a first surface that is in contact with the semiconductor chip and (ii) a second surface that is opposite to the first surface and in contact with the cathode. In some examples, the submount can be in direct contact with and connected to the cathode without a solder wire.

According to another aspect, a near-infrared laser package for an autonomous driving sensor includes a cap that defines a mounting space therein, a cathode that passes through the cap and extends to the mounting space, a submount disposed at the cathode, a semiconductor chip mounted to the submount and electrically connected to the cathode through the submount, and an anode that passes through the cap and extends to the mounting space, the anode being electrically connected to the semiconductor chip.

Implementations according to this aspect can include one or more of the following features and the features described above. For example, the submount can be made of an Si material. In some examples, the cathode can be configured to discharge heat generated from the semiconductor chip through the submount. In some examples, the submount can be in contact with and face the semiconductor chip.

In some implementations, the near-infrared laser package can further include a solder wire that connects the anode to the semiconductor chip. In some examples, the cathode and the anode can be spaced apart from each other.

In some examples, the submount can be in direct contact with and connected to the cathode without a solder wire. In some examples, the cathode can be disposed at a first side with respect to the semiconductor chip, and the anode can be disposed at a second side with respect to the semiconductor chip opposite to the first side. In some examples, the submount can have (i) a first surface that is in contact with the semiconductor chip and (ii) a second surface that is opposite to the first surface and in contact with the cathode.

According to the near-infrared laser package for an autonomous driving sensor of the present disclosure, it can be possible to increase heat transfer efficiency of a chip to package through material and structure development of a package, and reduce temperature dependency by increasing the heat dissipation effect through an electrode-junction layer-light-emitting layer (active layer) section.

Specifically, the electrically-conductive SI can be used as a submount to reduce or eliminate the bonding wires (e.g., 4 out of 8 in total).

In some implementations, copper (Cu) can be used for a stem, and the stem can be used as a cathode. Cu can exhibit superior low-temperature and high-temperature operation durability characteristics and thermal shock resistance durability characteristics compared to the use of the expensive high-heat dissipation aluminum nitride (AlN).

The low-temperature and high-temperature operation durability degradation rate can be less than 1%, and the thermal shock durability degradation rate can be reduced by up to 26% and an average of 8%.

In addition, the operating voltage is reduced, power conversion efficiency (PCE) is increased by up to 5%, and laser power consumption is reduced.

### BRIEF DESCRIPTION OF THE DRAWINGS

FIGS. 1 to 4 show semiconductor degradation phenomena caused by near-infrared laser packages in prior art.

FIG. 5 shows a structure of a near-infrared laser package in prior art.

FIG. 6 shows an example of a structure of a near-infrared laser package of the present disclosure.

FIG. 7 shows an example of a semiconductor chip of the near-infrared laser package of the present disclosure.

FIG. 8 shows an example of a heat dissipation path of the near-infrared laser package in prior art.

FIG. 9 shows an example of a heat dissipation path of the near-infrared laser package of the present disclosure.

FIG. 10 shows an example of light outputs of the near-infrared laser package of the present disclosure and a comparative example.

FIG. 11 shows an example of light outputs before and after thermal shock durability tests of the present disclosure and the comparative example.

FIG. 12 shows a comparison of power before and after driving tests.

FIG. 13 shows a comparison of voltages before and after driving tests.

FIG. 14 shows a comparison of threshold currents before and after driving tests.

FIG. 15 shows a comparison of wavelengths before and after driving tests.

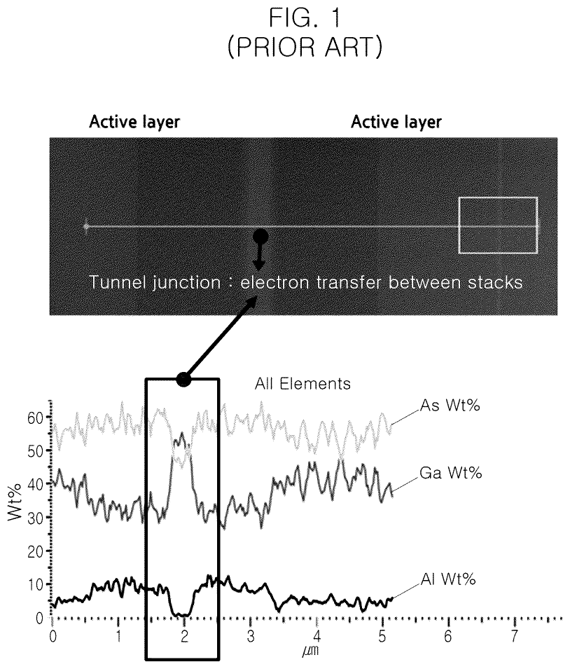

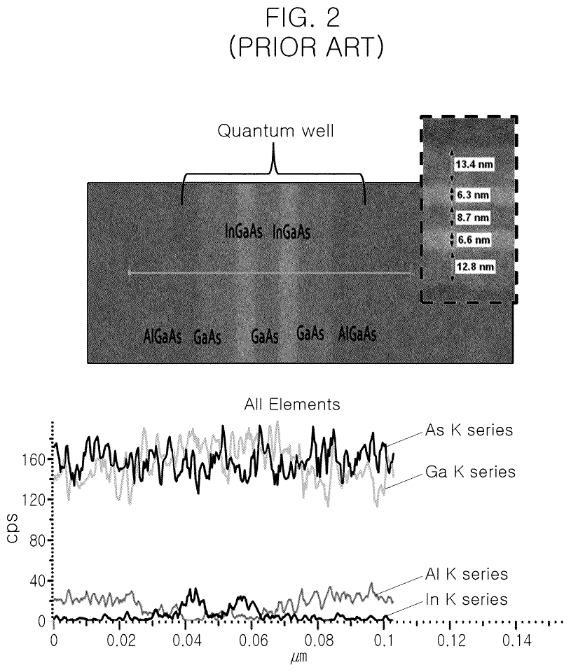

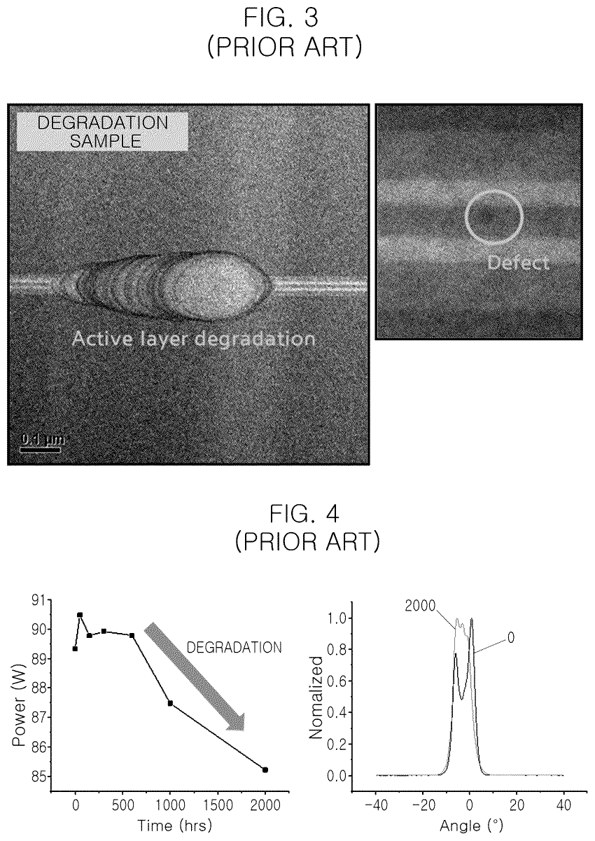

### DETAILED DESCRIPTION

For a full understanding of the present disclosure, operational advantages of the present disclosure, and objects to be achieved by practicing the present disclosure, reference should be made to the accompanying drawings, which example illustrate implementations of the present disclosure, and contents described in the accompanying drawings.

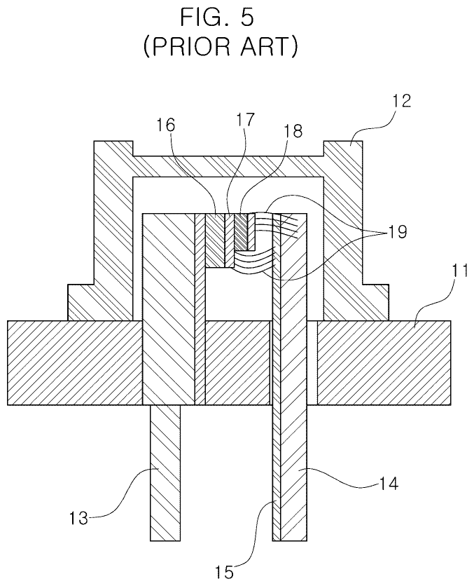

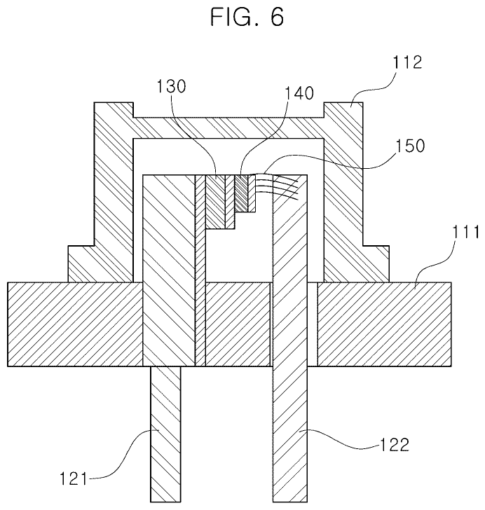

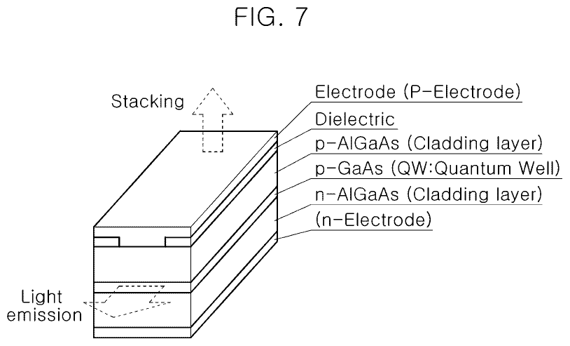

FIG. 5 shows a structure of a near-infrared laser package in prior art. FIG. 6 shows a structure of a near-infrared laser package of the present disclosure, and FIG. 7 shows an example of a semiconductor chip of the near-infrared laser package of the present disclosure. For example, as shown in FIG. 7, the semiconductor chip of the present disclosure can have a 4-stack structure in which an active layer composed of quantum and cladding is vertically stacked.

Hereinafter, a near-infrared laser package for an autonomous driving sensor according to an implementation of the present disclosure will be described with reference to FIGS. 5 to 7.

The near-infrared laser package of the present disclosure can provide an improved heat dissipation effect while increasing light output through a material perspective and a package configuration.

FIG. 5 shows the conventional near-infrared laser package having a semiconductor chip 18 embedded in a lower cap 11 and an upper cap 12, and a stem 13 extends to a mounting space through the lower cap 11 in order to mount the semiconductor chip 18. A submount 16 is disposed on the stem 13, and the semiconductor chip 18 is mounted on the submount 16. An anode 14 and a cathode 15 are disposed to extend to the mounting space through the lower cap 11 to face the stem 13, and the semiconductor chip 18 is connected to each of the anode 14 and the cathode 15 through a solder wire 19. Here, the stem 13 can be made of a metal material, such as Fe, and the submount 16 can be made of AlN. In addition, a coating layer 17 is formed on the submount 16 to be electrically connected to the semiconductor chip 18, and the coating layer 17 can be made of a material such as Ti, Pt, or Au.

The present disclosure describes a heat dissipation package that can improve the heat dissipation effect while increasing a light output through the electrically conductive structure by improving materials and structures of the submount and the stem corresponding to a heat transfer path generated from a chip.

In some implementations, the near-infrared laser package for an autonomous driving sensor of the present disclosure shown in FIG. 6 has a semiconductor chip 140 embedded in the lower cap 111 and the upper cap 112, and a stem 121 extends to the mounting space through a lower cap 111 in order to mount the semiconductor chip 140.

In some implementations, a submount 130 is disposed on the stem 121, and the semiconductor chip 140 is mounted on the submount 130.

The submount 130 of the present disclosure is made of an Si material and electrically communicates with the mounted semiconductor chip 140 without the coating layer on the conventional submount.

In some implementations, an anode 122 is disposed to extend to the mounting space through the lower cap 111 to face the stem 121, and the semiconductor chip 140 is connected to the anode 122 through a solder wire 150.

In some implementations, the stem 121 of the present disclosure can be made of a Cu material and function as a cathode as well as a stem.

Therefore, the submount 130 and the stem 121 as the negative electrode have a structure that is electrically connected and electrically conducts with the semiconductor chip 140, where the package in the present disclosure may not have a separate cathode configuration like the conventional one.

The AlN submount material of the conventional near-infrared laser package has a high thermal conductivity of about 170 W/mK, and thus can be used as a substrate of the chip to effectively remove heat generated from the chip. However, since the AlN submount material is a non-electrically conductive material, the cathode needs to be connected to an upper end of AlN coated with a metal (Ti/Pt/Au). In this case, electrodes can be formed on upper and lower ends of the chip to apply a current to the inside of the chip, and thus bonding wires are essential structures for both the cathode and the anode. However, there are disadvantages that AlN is expensive and thermal shock durability is vulnerable due to an increase in the number of bonding wires.

In some examples, according to the above-described structure of the present disclosure, the number of bonding wires can also be reduced by replacing the submount material considering that silicon (Si) has a thermal conductivity of 150 W/mK and is an electrically conductive material.

In addition, by replacing the material of the stem that functions as a fixing part of the package from conventional Fe to Cu, since silicon is an electrically conductive material, Cu can simultaneously function as a stem and cathode, thereby increasing the heat dissipation effect by Cu with thermal conductivity.

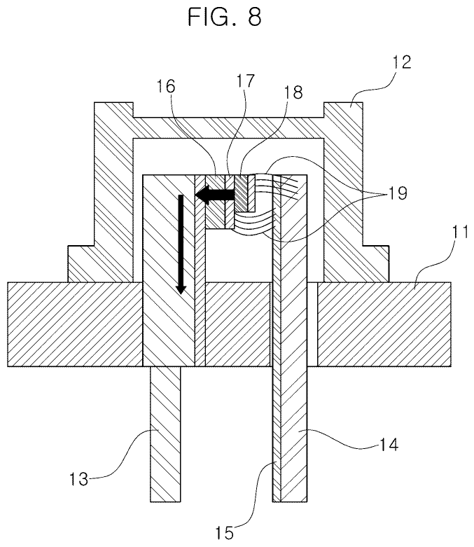

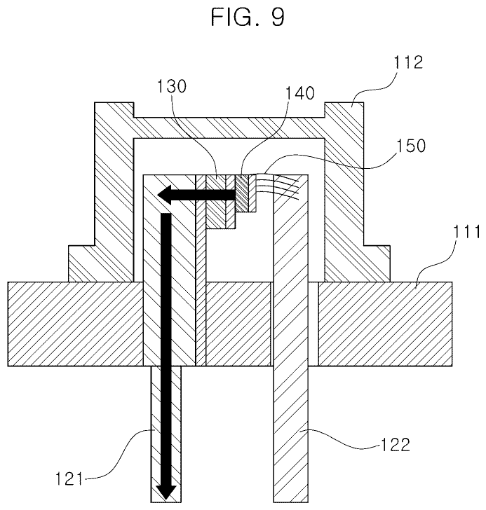

FIG. 8 shows a heat dissipation path of the conventional near-infrared laser package, and FIG. 9 shows a heat dissipation path of the near-infrared laser package of the present disclosure using arrows.

In the present disclosure, Cu having a thermal conductivity (372.1 W/m K) higher than Fe's thermal conductivity (72.1 W/m K) is used as a cathode so that the high heat generated from the chip can be more effectively removed through a structure in direct contact with the chip.

Hereinafter, to verify the effectiveness of the present disclosure, a package composed of an Si submount and a Cu stem according to the present disclosure and packages composed of five other comparative examples were manufactured and tested.

The comparative examples are a combination of an Si submount and an Fe stem, a combination of an Si submount and a Clad stem, a combination of an AlN submount and an Fe stem, a combination of an AlN submount and a Clad stem, and a combination of an AlN submount and a Cu stem.

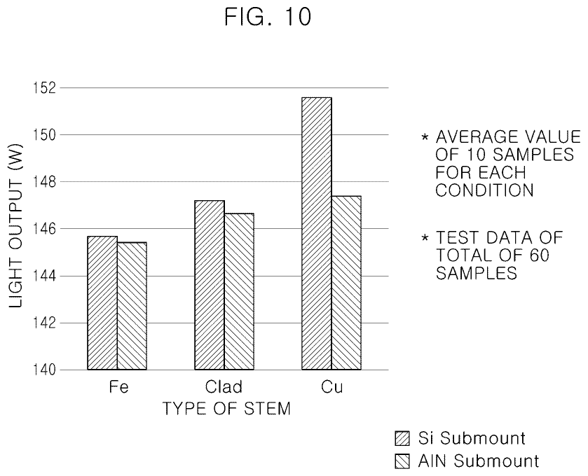

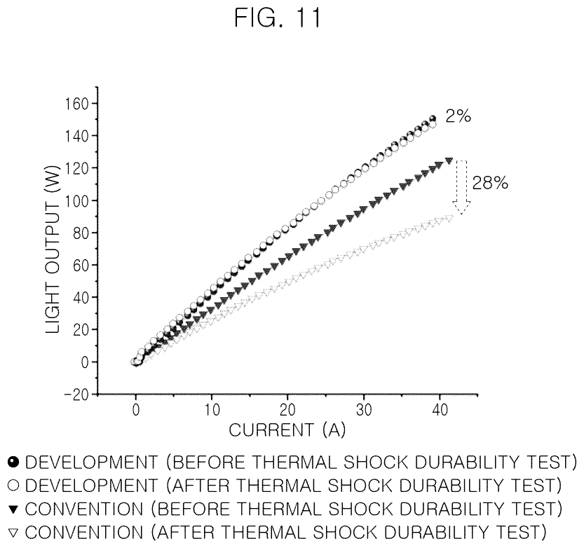

FIG. 10 shows the result of measuring light outputs of the present disclosure and a comparative example, and FIG. 11 shows the result of measuring light outputs before and after thermal shock durability test of the present disclosure and the comparative example.

The thermal shock test conditions are conditions in which a temperature ranges from −40° C. to 125° C., Tₘₐₓ and Tₘᵢₙ are each 30 minutes, Tᵣ (rising time) and T_{f} (falling time) are each 8 minutes, and a total of the time is 1,000 hours, and performance test was conducted after leaving the package in an environment of a non-operating state.

As can be seen in FIG. 10, the combination of the Si submount and the Cu stem showed the best light output (up to 152 W) in the present disclosure.

FIG. 11 shows that the effect of durability performance before and after a thermal shock is significantly greater in the structure of the present disclosure than in the combination of the AlN submount and the Fe stem.

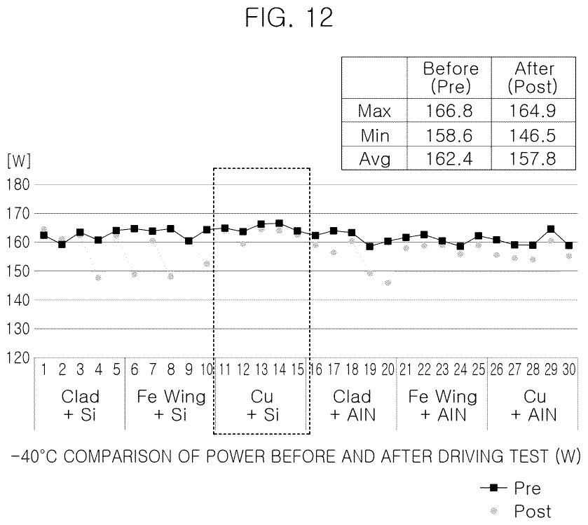

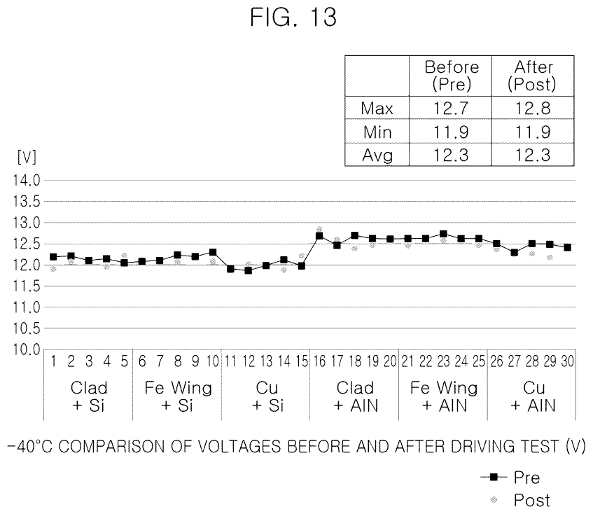

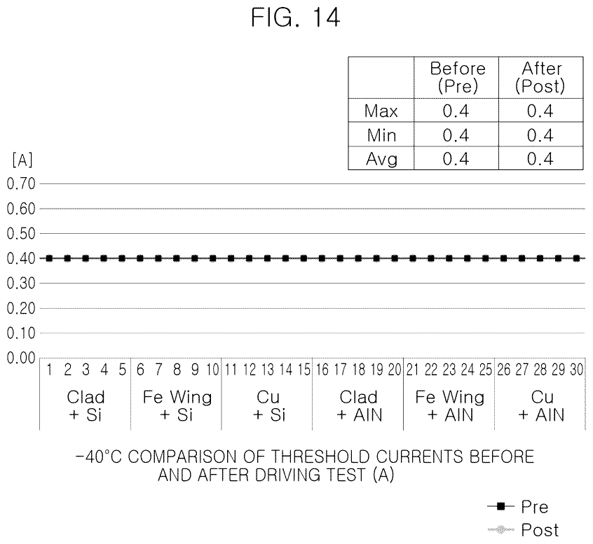

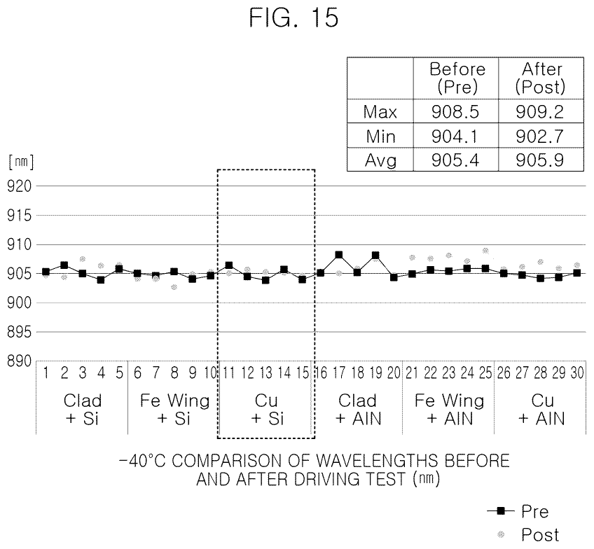

FIG. 12 shows a comparison of power before and after driving test, and FIG. 13 shows a comparison of voltages before and after driving test. In addition, FIG. 14 shows a comparison of threshold currents before and after driving test, and FIG. 15 shows a comparison of wavelengths before and after driving test.

As the result of the test of optical characteristics before and after a low-temperature operation at −40° C., in the case of the AlN submount, a change in light output during the low-temperature operation was found to be up to about 10%, and a change in spectrum was found to be the level of about 5 nm, and in the case of the Si submount, the change in optical output was found to be up to about 3%, and the change in spectrum was found to be the level of about 1 nm when the Cu stem was used.

In some examples, the change in light output and spectrum was the smallest in the combination of the Si submount and the Cu stem.

In some examples of comparing electrical performance, when power conversion efficiency (PCE) was calculated, the combination of the AlN and the Clad decreased to up to 28.9%, and the combination of Si and Cu stably maintained the PCE value at the level of 34%, which was very advantageous in terms of power consumption.

Furthermore, as the result of measuring the operating voltage while changing the number of bonding wires, the number of cathode bonding wires may affect the operating voltage. Therefore, since the AlN submount is a non-conductive type, the operating voltage increases as the bonding wire is connected to the cathode.

In the present disclosure, since the stem itself is used as a cathode while the Si submount is used, the bonding wire for a cathode is unnecessary, resulting in increased PCE and reduced power consumption due to the reduced operating voltage.

For example, when the number of bonding wires changes from 4 to 2, the cathode increases by 0.4 V and the anode increases by 0.2 V.

In some implementations, since the Si submount is used in the present disclosure, the number of bonding wires for a cathode can be reduced by half, and there was no voltage increase effect, and rather, the operating voltage was reduced by about 1 V.

Although the present disclosure has been described above with reference to the exemplary drawings, the present disclosure is not limited to the described implementations, and it is apparent to those skilled in the art that various modifications and changes can be made without departing from the spirit and scope of the present disclosure. Therefore, these modified examples or changed examples should be included in the claims of the present disclosure, and the scope of the present disclosure should be construed based on the appended claims.

What is claimed is:

1. A near-infrared laser package for an autonomous driving sensor, comprising:
a cap that defines a mounting space therein;
a stem that passes through the cap and extends to the mounting space;
a submount disposed at the stem;
a semiconductor chip mounted to the submount and electrically connected to the stem through the submount; and
an anode that passes through the cap and extends to the mounting space, the anode being electrically connected to the semiconductor chip.

2. The near-infrared laser package of claim 1, wherein the stem is a cathode that is made of a copper (Cu) material.

3. The near-infrared laser package of claim 2, wherein the submount is made of a silicon (Si) material.

4. The near-infrared laser package of claim 3, wherein the stem is configured to discharge heat generated from the semiconductor chip through the submount.

5. The near-infrared laser package of claim 3, wherein the submount is in contact with and faces the semiconductor chip.

6. The near-infrared laser package of claim 2, wherein the anode faces a surface of the semiconductor chip.

7. The near-infrared laser package of claim 6, further comprising a solder wire that connects the anode to the semiconductor chip.

8. The near-infrared laser package of claim 2, wherein the cathode and the anode are spaced apart from each other.

9. The near-infrared laser package of claim 8, wherein the cathode is disposed at a first side with respect to the semiconductor chip, and
wherein the anode is disposed at a second side with respect to the semiconductor chip opposite to the first side.

10. The near-infrared laser package of claim 2, wherein the submount has (i) a first surface that is in contact with the semiconductor chip and (ii) a second surface that is opposite to the first surface and in contact with the cathode.

11. The near-infrared laser package of claim 2, wherein the submount is in direct contact with and connected to the cathode without a solder wire.

12. A near-infrared laser package for an autonomous driving sensor, comprising:
a cap that defines a mounting space therein;
a cathode that passes through the cap and extends to the mounting space;
a submount disposed at the cathode;
a semiconductor chip mounted to the submount and electrically connected to the cathode through the submount; and
an anode that passes through the cap and extends to the mounting space, the anode being electrically connected to the semiconductor chip.

13. The near-infrared laser package of claim 12, wherein the submount is made of an Si material.

14. The near-infrared laser package of claim 13, wherein the cathode is configured to discharge heat generated from the semiconductor chip through the submount.

15. The near-infrared laser package of claim 13, wherein the submount is in contact with and faces the semiconductor chip.

16. The near-infrared laser package of claim 13, further comprising a solder wire that connects the anode to the semiconductor chip.

17. The near-infrared laser package of claim 13, wherein the cathode and the anode are spaced apart from each other.

18. The near-infrared laser package of claim 13, wherein the submount is in direct contact with and connected to the cathode without a solder wire.

19. The near-infrared laser package of claim 12, wherein the cathode is disposed at a first side with respect to the semiconductor chip, and
wherein the anode is disposed at a second side with respect to the semiconductor chip opposite to the first side.

20. The near-infrared laser package of claim 12, wherein the submount has (i) a first surface that is in contact with the semiconductor chip and (ii) a second surface that is opposite to the first surface and in contact with the cathode.
